(19) United States
(12) Patent Application Publication
(10) Pub. No.: US 2026/0066844 A1
(43) Pub. Date: Mar. 5, 2026

(54) PHOTOVOLTAIC PANEL SYSTEM

(71) Applicant: Benjamin Ramos-Negron, Bayamon, PR (US)

(72) Inventor: Benjamin Ramos-Negron, Bayamon, PR (US)

(21) Appl. No.: 18/822,082

(22) Filed: Aug. 30, 2024

(51) Int. Cl. H02S 40/30; F21S 8/00; F21Y 105/16; F21Y 115/10; H02S 20/20; H05B 45/10; H05B 47/11

(52) U.S. Cl. CPC H02S 40/30; F21S 8/006; H02S 20/20; H05B 45/10; H05B 47/11; F21Y 2105/16; F21Y 2115/10

(57) ABSTRACT

[Purpose] A display device that eliminates the use of commercial power, enabling savings in equipment costs and electrical energy.

[Configuration] The display board (11) is made of a colored, transparent plate material that has been mixed with a fluorescent material and is structured so that light absorbed from the outside by this fluorescent material can be emitted from the periphery of the display board (11), and solar cells (15) that charge a charger (16) are arranged around the periphery of the display board (11). During the day, the display board (11) absorbs natural light to display and the charger (16) is charged by the solar cells (15), and at night, the display board (11) emits light using power from the charger (16).

### BACKGROUND OF THE INVENTION

### 1) Field of the Invention

The present disclosure relates to photovoltaic systems, and more particularly to a photovoltaic panel system with integrated night illumination for continuous electricity generation.

### 2) Description of Related Art

Photovoltaic systems have become increasingly popular as a renewable energy source, harnessing solar energy to generate electricity. Traditional photovoltaic panels are designed to capture sunlight during daytime hours, converting it into usable electrical power. However, these conventional systems face a significant limitation in their inability to generate electricity during nighttime hours when sunlight is unavailable.

To address this limitation, many solar energy systems incorporate battery storage solutions to use energy during the night period. These batteries are charging during the day for use at night or during periods of low sunlight. While effective, battery storage systems often come with substantial costs, both in terms of initial investment and ongoing maintenance. Additionally, batteries have limited lifespans and can pose environmental concerns upon disposal.

Bifacial photovoltaic panels represent an advancement in solar technology, capable of capturing light from both their front and rear surfaces. This design allows for increased energy production by utilizing reflected light from surrounding surfaces. However, even bifacial panels are traditionally limited to daytime energy generation.

The intermittent nature of fossil energy production presents challenges for grid stability and reliable power supply. As the adoption of renewable energy sources increases, there is a growing need for solutions that can provide more consistent energy output from solar installations.

Efforts to improve the efficiency and reliability of solar energy systems have led to various innovations in panel design, energy storage, and system integration. However, there remains a need for solutions that can extend the productive hours of photovoltaic systems without relying solely on expensive battery storage options.

### BRIEF SUMMARY OF THE INVENTION

According to an aspect of the present disclosure, a photovoltaic panel system for continual power production is provided. The photovoltaic panel system includes a bifacial photovoltaic panel having a front side and a back side, wherein the bifacial photovoltaic panel uses sunlight to generate electricity from light incident on both the front side and the back side. The system also includes a solar lamp positioned adjacent to the back side of the bifacial photovoltaic panel. A controller is configured to activate the solar lamp during nighttime hours. The solar lamp, when activated, illuminates the back side of the bifacial photovoltaic panel to enable electricity generation during nighttime hours.

According to other aspects of the present disclosure, the photovoltaic panel system may include one or more of the following features. The solar lamp may comprise a plurality of LED lights. The plurality of LED lights may be arranged in a panel configuration. The system may further include a mounting structure configured to secure the bifacial photovoltaic panel and the solar lamp in a fixed position relative to each other. The mounting structure may comprise anchors to withstand strong winds. The controller may be further configured to adjust the intensity of the solar lamp based on ambient light conditions. The controller may be configured to activate the solar lamp at a lower intensity during twilight hours and at a higher intensity during full nighttime hours.

According to another aspect of the present disclosure, a method of generating electricity using a photovoltaic panel system for continual power production is provided. The method includes providing a bifacial photovoltaic panel having a front side and a back side. The method also includes positioning a solar lamp adjacent to the back side of the bifacial photovoltaic panel. The method further includes generating electricity from light incident on the front side of the bifacial photovoltaic panel during daytime hours. The method also includes activating the solar lamp during nighttime hours. The method further includes generating electricity from light emitted by the solar lamp and incident on the back side of the bifacial photovoltaic panel during nighttime hours.

According to other aspects of the present disclosure, the method may include one or more of the following features. The method may further include adjusting an intensity of the solar lamp based on ambient light conditions. Adjusting the intensity of the solar lamp may comprise activating the solar lamp at a lower intensity during twilight hours and at a higher intensity during full nighttime hours. The method may further include securing the bifacial photovoltaic panel and the solar lamp in a fixed position relative to each other using a mounting structure. The mounting structure may comprise anchors configured to withstand strong winds. The solar lamp may comprise a plurality of LED lights arranged in a panel configuration. Positioning the solar lamp adjacent to the back side of the bifacial photovoltaic panel may comprise attaching the panel configuration of LED lights to the back side of the bifacial photovoltaic panel using a plurality of screws.

According to another aspect of the present disclosure, a renewable energy system is provided. The photovoltaic panel system includes a bifacial photovoltaic panel. The system also includes a light source positioned to illuminate a back side of the bifacial photovoltaic panel. The system further includes a control unit configured to operate the solar lamp to generate electricity and activate the light source during nighttime hours to enable the bifacial photovoltaic panel to generate electricity from light emitted by the light source.

According to other aspects of the present disclosure, the photovoltaic panel system may include one or more of the following features. The light source may comprise a plurality of LED lights arranged in a panel configuration. The panel configuration of LED lights may be attached to the back side of the bifacial photovoltaic panel using a plurality of screws. The system may further include a mounting structure configured to secure the bifacial photovoltaic panel and the light source in a fixed position relative to each other. The mounting structure may comprise anchors configured to withstand strong winds. The control unit may be further configured to adjust an intensity of the light source based on ambient light conditions, activating the light source at a lower intensity during twilight hours and at a higher intensity during full nighttime hours.

These and other objects, features, and advantages of the present invention will become more readily apparent from the attached drawings and the detailed description of the preferred embodiments, which follow.

### BRIEF DESCRIPTION OF THE DRAWINGS

A further understanding of the nature and advantages of particular embodiments may be realized by reference to the remaining portions of the specification and the drawings, in which like reference numerals are used to refer to similar components. When reference is made to a reference numeral without specification to an existing sub-label, it is intended to refer to all such multiple similar components.

FIG. 1 shows an unscaled perspective view of a first embodiment of a photovoltaic panel system;

FIG. 2 shows a perspective view of a second embodiment of a solar lamp example according to the present invention;

FIG. 3 shows a perspective view of a third embodiment of a photovoltaic panel system according to the present invention;

FIG. 4 is a cross-sectional view of a mono-facial photovoltaic panel; and

FIG. 5 is a cross-sectional view of a bi-facial photovoltaic panel.

Corresponding reference characters indicate corresponding parts throughout the several views. The exemplifications set out herein illustrate embodiments of the invention and such exemplifications are not to be construed as limiting the scope of the invention in any manner.

### DETAILED DESCRIPTION

While various aspects and features of certain embodiments have been summarized above, the following detailed description illustrates a few exemplary embodiments in further detail to enable one skilled in the art to practice such embodiments. The described examples are provided for illustrative purposes and are not intended to limit the scope of the invention.

In the following description, for the purposes of explanation, numerous specific details are set forth in order to provide a thorough understanding of the described embodiments. It will be apparent to one skilled in the art however that other embodiments of the present invention may be practiced without some of these specific details. Several embodiments are described herein, and while various features are ascribed to different embodiments, it should be appreciated that the features described with respect to one embodiment may be incorporated with other embodiments as well. By the same token however, no single feature or features of any described embodiment should be considered essential to every embodiment of the invention, as other embodiments of the invention may omit such features.

In this application the use of the singular includes the plural unless specifically stated otherwise and use of the terms “and” and “or” is equivalent to “and/or,” also referred to as “non-exclusive or” unless otherwise indicated. Moreover, the use of the term “including,” as well as other forms, such as “includes” and “included,” should be considered non-exclusive. Also, terms such as “element” or “component” encompass both elements and components including one unit and elements and components that include more than one unit, unless specifically stated otherwise.

Lastly, the terms “or” and “and/or” as used herein are to be interpreted as inclusive or meaning any one or any combination. Therefore, “A, B or C” or “A, B and/or C” mean “any of the following: A; B; C; A and B; A and C; B and C; A, B and C.” An exception to this definition will occur only when a combination of elements, functions, steps or acts are in some way inherently mutually exclusive.

As this invention is susceptible to embodiments of many different forms, it is intended that the present disclosure be considered as an example of the principles of the invention and not intended to limit the invention to the specific embodiments shown and described.

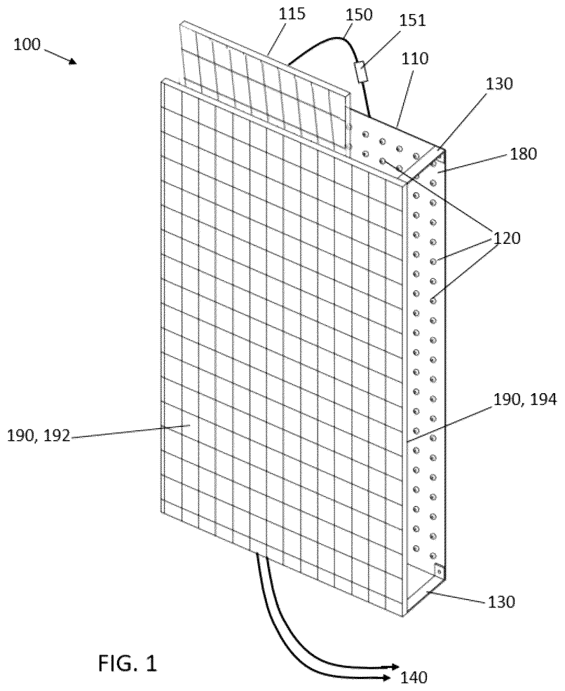

FIG. 1 shows an unscaled perspective view of a first embodiment of a photovoltaic panel system 100 for continuous power production. This system includes a bifacial photovoltaic panel 190 and a solar lamp 110, 115. The bifacial photovoltaic panel 190 has a front side 192 and a back side 194 for generation of electricity from solar lamp 110, 115. A solar lamp 110 having a plurality of LEDs 120 on a lamp face 180 is positioned adjacent to the back side 194 of the bifacial photovoltaic panel 190 and is activated during nighttime hours, illuminating the back side 194 of the bifacial photovoltaic panel 190 and enabling electricity generation during the nighttime hours. Brackets 130 hold the bifacial photovoltaic panel 190 and the solar lamp 110 in a fixed position to one another. The photovoltaic panel system 100 includes output wires 140 from bifacial panel 190 and output wires 150 from the monofacial panel 115 to the solar lamp 110. A connector 151 may be used to allow temporary disconnection of the monofacial panel 315 or for replacement of the monofacial panel 315.

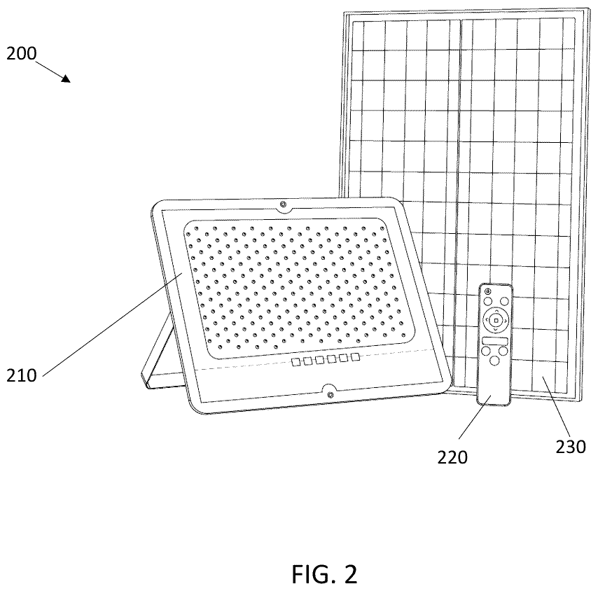

FIG. 2 shows an unscaled perspective view of another embodiment of photovoltaic panel system 200 for continuous power production. This system includes a monofacial photovoltaic panel 230, a solar lamp 210 movable with respect to the monofacial photovoltaic panel 230, and a controller 220. The bifacial photovoltaic panel 190 has a front side and a back side which generates electricity from sunlight on the front side and a solar lamp at the back side. The solar lamp 210 is positioned adjacent to the back side of the bifacial photovoltaic panel 190 and is activated during nighttime hours, illuminating the back side of the bifacial photovoltaic panel 190, 390 and enabling electricity generation during the nighttime hours. The controller 220 may be configured to activate the solar lamp 210 based on ambient light conditions, allowing for dynamic adjustment of the solar lamp intensity. The activation of the solar lamp 210 may be determined by a sensor for sensing sunlight, the sensor placed on the solar lamp 210 or with a wired or wireless signal. Alternately, the activation of the solar lamp 210 is determined by a light source other than sunlight and determined by the controller 220.

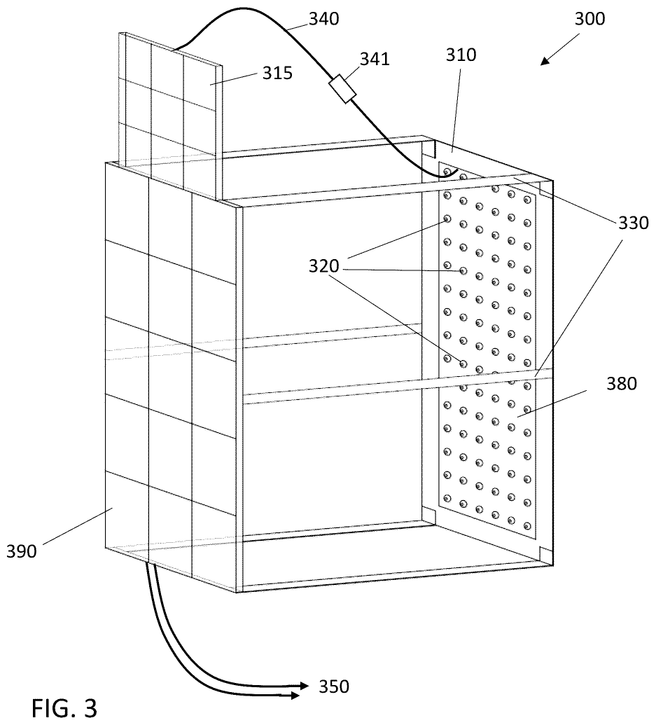

FIG. 3 shows an unscaled perspective view of yet another embodiment of a photovoltaic panel system 300 for continuous power production. This system includes a bifacial photovoltaic panel 390 and a solar lamp 310. The bifacial photovoltaic panel 390 has a front side and a back side for generation of electricity from sunlight on the front side and the back side. A solar lamp 310 having a plurality of LEDs 320 on a lamp face 380 is positioned adjacent to the back side of the bifacial photovoltaic panel 390 and is activated during nighttime hours, illuminating the back side of the bifacial photovoltaic panel 390 and enabling electricity generation during the nighttime hours. The photovoltaic panel system 300 includes a monofacial panel 315 with the sunlight for powering the solar lamp 310. Brackets 330 hold the bifacial photovoltaic panel 390 and the solar lamp 310 in a fixed position to one another. The photovoltaic panel system 300 includes output wires 350 from bifacial panel 390 and output wires 340 from the monofacial panel 315 to the solar lamp 310. A connector 341 may be used to allow temporary disconnection of the monofacial panel 315 or for replacement of the monofacial panel 315.

Although the photovoltaic panel systems 100, 300 use a solar light 200 to produce power at nighttime and power from monofacial panels 115, 315 is needed to run the solar light, there are industries which require their systems to have a continuous source of power maintained from a single source and the photovoltaic panel systems 100, 300 use the solar light to maintain the single source of power to the industry systems.

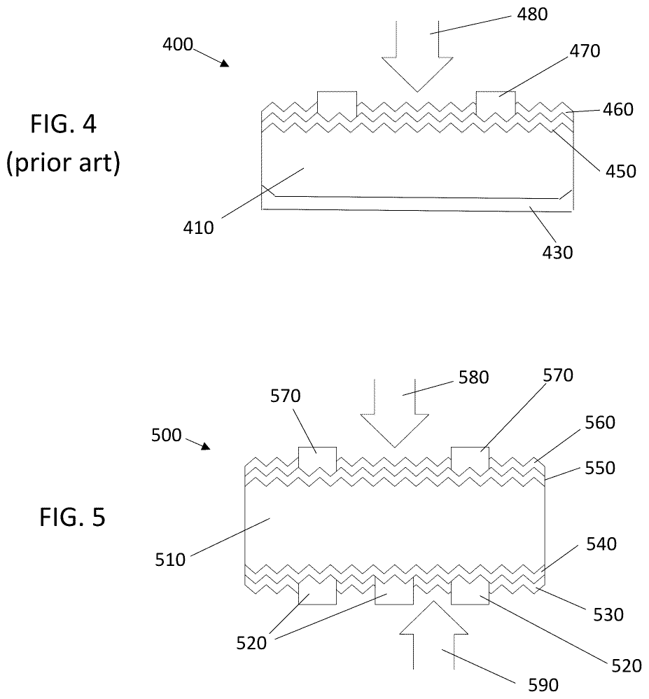

FIG. 4 is a cross-sectional view of a mono-facial photovoltaic panel 400 which is considered prior art. The mono-facial photovoltaic panel 400 includes an Al-BSF base 430 and a p-type wafer 410 disposed on the base 430. An emitter (n+Si) 450 is disposed between the p-type wafer 410 and a front passivation & AR 460. The front contacts 470 allow the electricity to pass to a point of use, battery, inverter or other component. The sunlight 480 striking the mono-facial photovoltaic panel 400 allows the generation of voltage to the output contacts.

FIG. 5 is a cross-sectional view of a bi-facial photovoltaic panel 500. The bi-facial photovoltaic panel 500 includes an n-type wafer 510 disposed between an emitter (p+Si) 550 and BSF (n+Si) 540. A front passivation & AR 560 is disposed on the emitter (p+Si) 550 and a rear passivation 530 is disposed on the BSF (n+Si) 540. The front contacts 570 allow the electricity to pass to a point of use, battery, inverter or other component from the light striking the front side. The rear contacts 520 allow the electricity to pass to a point of use, battery, inverter or other component from the light striking the rear side. The sunlight 580, 590 striking the front face and the rear face of the bi-facial photovoltaic panel 500, respectively, allows the generation of voltage to the front contacts 570 and the rear contacts 520.

This photovoltaic panel system may provide a solution for continuous electricity production, reducing reliance on battery storage and potentially improving overall system efficiency.

In some aspects, a photovoltaic panel system for continual power production may be provided. This system may include a bifacial photovoltaic panel, a solar lamp, and a controller. The bifacial photovoltaic panel may have a front side and a back side, and may be configured to generate electricity from sunlight on the front side and the back side. This dual-sided design may allow for increased energy production, as light can be harvested from both sides of the panel.

The solar lamp may be positioned adjacent to the back side of the bifacial photovoltaic panel. In some cases, the solar lamp may be integrated into the panel itself, while in other cases, it may be a separate component that is positioned in close proximity to the panel. The solar lamp may be designed to illuminate the back side of the bifacial photovoltaic panel, enabling the panel to continue generating electricity even during nighttime hours when natural sunlight is not available.

The controller may be configured to activate the solar lamp during nighttime hours. In some cases, the controller may also be configured to adjust the intensity of the solar lamp based on ambient light conditions. For example, the controller may activate the solar lamp at a lower intensity during twilight hours and at a higher intensity during full nighttime hours. This may allow for more efficient use of the solar lamp's energy and may help to extend the lifespan of the lamp.

In some aspects, the photovoltaic panel system may be designed for continual power production, providing a reliable source of electricity both day and night. This may be particularly beneficial in areas where access to a reliable power grid is limited or non-existent. The bifacial photovoltaic system may also offer a more sustainable and environmentally friendly alternative to traditional power sources, as it harnesses the power of the sun to generate electricity.

In some aspects, the bifacial photovoltaic panel may be designed with a front side and a back side, both capable of generating electricity from light. This dual-sided design may allow for increased energy production, as light can be harvested from both sides of the panel. The front side of the bifacial photovoltaic panel may be primarily exposed to direct sunlight during the day, while the back side may be exposed to reflected light from solar lamps.

In some cases, the bifacial photovoltaic panel may utilize reflected light from the ground or neighboring rows of PV modules. This may allow the panel to generate electricity even when the front side is not directly exposed to sunlight, such as during the early morning or late afternoon hours when the sun is low in the sky. The ability to utilize reflected light may increase the overall efficiency of the bifacial photovoltaic panel, as it can generate electricity throughout the day, regardless of the sun's position in the sky.

In some aspects, the back side of the bifacial photovoltaic panel may include a symmetrical cell structure for additional sunlight absorption. This symmetrical cell structure may be designed to absorb sunlight from both the front and the back, further enhancing the panel's ability to generate electricity from light incident on both sides. The symmetrical cell structure may be particularly beneficial during the middle of the day, when the sun is at its highest point in the sky and light is being reflected off the ground and onto the back side of the panel.

In some cases, the bifacial photovoltaic panel may be designed with different sizes and capacities, depending on the specific needs and requirements of the installation. For example, a 400-watt bifacial photovoltaic panel may have different measurements than a 450-watt bifacial photovoltaic panel. This flexibility in design may allow the bifacial photovoltaic panel to be customized to fit a wide range of applications and environments.

In some aspects, the solar lamp may be positioned adjacent to the back side of the bifacial photovoltaic panel. The positioning of the solar lamp may be such that it illuminates the back side of the bifacial photovoltaic panel when activated. This positioning may be achieved in a variety of ways. For instance, the solar lamp may be attached directly to the back side of the bifacial photovoltaic panel, or it may be positioned in close proximity to the panel, such as on a mounting structure that holds both the panel and the lamp.

The solar lamp may be designed to emit light of sufficient intensity to enable the bifacial photovoltaic panel to generate electricity during nighttime hours. In some cases, the solar lamp may comprise a plurality of LED lights. These LED lights may be arranged in a panel configuration, which may allow for a more uniform distribution of light across the back side of the bifacial photovoltaic panel.

In some aspects, the solar lamp is activated during nighttime hours. This activation may be controlled by a controller, which may be configured to activate the solar lamp when ambient light conditions indicate that it is nighttime. The controller may also be configured to adjust the intensity of the solar lamp based on these ambient light conditions. For example, the controller may activate the solar lamp at a lower intensity during twilight hours and at a higher intensity during full nighttime hours. This may allow for more efficient use of the solar lamp's energy and may help to extend the lifespan of the lamp.

In some cases, the solar lamp may be selected based on its ability to integrate with the bifacial photovoltaic panel. For instance, a solar lamp suitable for a 400-watt bifacial photovoltaic panel may have different specifications than a solar lamp suitable for a 450-watt bifacial photovoltaic panel. This flexibility in the selection of the solar lamp may allow for the bifacial photovoltaic system to be customized to fit a wide range of applications and environments.

In some aspects, the controller may be configured to activate the solar lamp during nighttime hours. This activation may be based on a variety of factors, such as the level of ambient light or the time of day. For instance, the controller may be programmed to activate the solar lamp when the level of ambient light falls below a certain threshold, indicating that it is nighttime. Alternatively, the controller may be programmed to activate the solar lamp at a specific time of day, such as sunset.

In some cases, the controller may also be configured to adjust the intensity of the solar lamp based on ambient light conditions. This adjustment may be made in real-time, allowing the intensity of the solar lamp to be dynamically adjusted as ambient light conditions change. For example, the controller may be configured to increase the intensity of the solar lamp as the level of ambient light decreases, ensuring that the bifacial photovoltaic panel continues to generate electricity even as natural sunlight fades.

In some aspects, the controller may be configured to activate the solar lamp at a lower intensity during twilight hours and at a higher intensity during full nighttime hours. This may allow for more efficient use of the solar lamp's energy, as the lamp can be operated at a lower intensity when there is still some natural sunlight available, and at a higher intensity when it is fully dark. This feature may also help to extend the lifespan of the solar lamp, as operating the lamp at a lower intensity can reduce wear and tear on the lamp's components.

In some cases, the controller may be a standalone device that is connected only to the solar lamp. In other cases, the controller may be integrated into the bifacial photovoltaic panel or the solar lamp. Regardless of its physical configuration, the controller may be designed to communicate with the solar lamp, allowing it to control the operation of the solar lamp based on the performance of the bifacial photovoltaic panel and the level of ambient light.

In some aspects, a mounting structure may be utilized to secure the bifacial photovoltaic panel and the solar lamp in a fixed position relative to each other. This mounting structure may be designed to hold both the bifacial photovoltaic panel and the solar lamp in a specific orientation that maximizes the efficiency of the system. For instance, the mounting structure may position the solar lamp such that it illuminates the back side of the bifacial photovoltaic panel when activated. The mounting structure may be adjustable, allowing the orientation of the bifacial photovoltaic panel and the solar lamp to be changed as needed to optimize the system's performance under different environmental conditions.

In some cases, the mounting structure may comprise anchors designed to withstand strong winds. These anchors may be used to secure the mounting structure, and by extension the bifacial photovoltaic panel and the solar lamp, to a surface such as the ground or a rooftop. The use of anchors may provide additional stability to the system, helping to prevent damage or displacement due to high winds or other adverse weather conditions. The anchors may be made of a durable material, such as stainless steel, to resist corrosion and wear.

In some aspects, the mounting structure may be designed to accommodate different sizes and capacities of bifacial photovoltaic panels and solar lamps. For example, the mounting structure may include adjustable components that can be repositioned to fit a 400-watt bifacial photovoltaic panel or a 450-watt bifacial photovoltaic panel. This flexibility in design may allow the mounting structure to be used with a wide range of bifacial photovoltaic panels and solar lamps, making it a versatile component of the bifacial photovoltaic system.

In some cases, the mounting structure may be designed for easy installation and maintenance. For instance, the mounting structure may include features that allow the bifacial photovoltaic panel and the solar lamp to be easily attached and detached, facilitating installation and maintenance tasks. The mounting structure may also include features that allow the orientation of the bifacial photovoltaic panel and the solar lamp to be easily adjusted, enabling the system's performance to be optimized for different environmental conditions.

In some aspects, the solar lamp may comprise a plurality of LED lights. These LED lights may be arranged in a panel configuration, which may allow for a more uniform distribution of light across the back side of the bifacial photovoltaic panel. The panel configuration of LED lights may be designed to provide sufficient illumination to enable the bifacial photovoltaic panel to generate electricity during nighttime hours. The use of LED lights may offer several advantages, such as high energy efficiency, long lifespan, and the ability to produce a high intensity of light.

In some cases, the panel configuration of LED lights may be attached to the back side of the bifacial photovoltaic panel. This attachment may be achieved using a plurality of screws, which may secure the panel configuration of LED lights to the bifacial photovoltaic panel. The screws may be made of a durable material, such as stainless steel, to resist corrosion and wear. The use of screws may provide a secure attachment while also allowing for easy installation and removal of the panel configuration of LED lights, facilitating maintenance tasks.

In other cases, the panel configuration of LED lights may be attached to the back side of the bifacial photovoltaic panel using other attachment methods. For instance, the panel configuration of LED lights may be attached using clips, brackets, adhesive, or other suitable attachment means. The specific attachment method used may depend on various factors, such as the design of the bifacial photovoltaic panel and the panel configuration of LED lights, the environmental conditions in which the system is installed, and the specific requirements of the installation.

In some aspects, the panel configuration of LED lights may be designed to be easily replaceable. This may allow for easy maintenance and replacement of the LED lights, extending the lifespan of the solar lamp and the overall bifacial photovoltaic system. The panel configuration of LED lights may also be designed to be resistant to environmental factors, such as moisture, dust, and temperature fluctuations, ensuring reliable operation under a wide range of conditions.

In some aspects, the controller may be configured to adjust the intensity of the solar lamp based on ambient light conditions. This adjustment may be made in real-time, allowing the intensity of the solar lamp to be dynamically adjusted as ambient light conditions change. For example, the controller may be configured to increase the intensity of the solar lamp as the level of ambient light decreases, ensuring that the bifacial photovoltaic panel continues to generate electricity even as natural sunlight fades.

In some cases, the controller may be configured to activate the solar lamp at a lower intensity during twilight hours and at a higher intensity during full nighttime hours. This may allow for more efficient use of the solar lamp's energy, as the lamp can be operated at a lower intensity when there is still some natural sunlight available, and at a higher intensity when it is fully dark. This feature may also help to extend the lifespan of the solar lamp, as operating the lamp at a lower intensity can reduce wear and tear on the lamp's components.

In other cases, the controller may be configured to adjust the intensity of the solar lamp based on a predetermined schedule. For instance, the controller may be programmed to activate the solar lamp at a lower intensity during the early evening hours, and gradually increase the intensity as the night progresses. This may allow for a more gradual transition from natural sunlight to artificial light, which may be beneficial in certain applications.

In some aspects, the controller may be configured to adjust the intensity of the solar lamp based on the performance of the bifacial photovoltaic panel. For example, if the bifacial photovoltaic panel is generating less electricity than expected during the day, the controller may increase the intensity of the solar lamp during the night to compensate for the reduced daytime energy production. This may help to ensure a consistent level of electricity production from the bifacial photovoltaic system, regardless of variations in daytime sunlight conditions.

In some cases, the controller may be configured to adjust the intensity of the solar lamp based on the energy storage capacity of the system. For instance, if the system includes a battery or other energy storage device, the controller may increase the intensity of the solar lamp when the energy storage device is fully charged, and decrease the intensity when the energy storage device is nearing depletion. This may help to optimize the use of stored energy and extend the operating time of the system.

In some aspects, the panel holding the lights, which may be a plurality of LED lights arranged in a panel configuration, may be made of ¼″ PVC. This material may be chosen for its durability, resistance to environmental factors, and ease of fabrication. The use of PVC may also provide cost benefits, as it is a relatively inexpensive material. In other cases, the panel holding the lights may be made of other suitable materials, such as metal, glass, or composite materials, depending on the specific requirements of the installation.

In some cases, the panel holding the lights may be attached to the back side of the bifacial photovoltaic panel using a plurality of screws. For instance, 8 Stainless Steel 1-½″×¼″ screws may be used to secure the panel holding the lights to the bifacial photovoltaic panel. The use of stainless steel screws may provide a secure attachment while also resisting corrosion and wear. In other cases, different types or sizes of screws may be used, or other attachment methods may be employed, such as clips, brackets, or adhesive.

In some aspects, the panel holding the lights may be designed to be easily replaceable. This may allow for easy maintenance and replacement of the lights, extending the lifespan of the solar lamp and the overall bifacial photovoltaic system. The panel holding the lights may also be designed to be resistant to environmental factors, such as moisture, dust, and temperature fluctuations, ensuring reliable operation under a wide range of conditions.

In some cases, the photovoltaic panel system may be installed in a variety of locations, such as rooftops, open fields, or other areas with ample sunlight exposure. The system may be particularly beneficial in areas where access to a reliable power grid is limited or non-existent, providing a reliable source of electricity both day and night. The system may also be used in commercial or industrial settings, where it may help to reduce energy costs and promote sustainability.

Since many modifications, variations, and changes in detail can be made to the described embodiments of the invention, it is intended that all matters in the foregoing description and shown in the accompanying drawings be interpreted as illustrative and not in a limiting sense. Furthermore, it is understood that any of the features presented in the embodiments may be integrated into any of the other embodiments unless explicitly stated otherwise. The scope of the invention should be determined by the appended claims and their legal equivalents.

In addition, the present invention has been described with reference to embodiments, it should be noted and understood that various modifications and variations can be crafted by those skilled in the art without departing from the scope and spirit of the invention. Accordingly, the foregoing disclosure should be interpreted as illustrative only and is not to be interpreted in a limiting sense. Further it is intended that any other embodiments of the present invention that result from any changes in application or method of use or operation, method of manufacture, shape, size, or materials which are not specified within the detailed written description or illustrations contained herein are considered within the scope of the present invention.

Insofar as the description above and the accompanying drawings disclose any additional subject matter that is not within the scope of the claims below, the inventions are not dedicated to the public and the right to file one or more applications to claim such additional inventions is reserved.

Although very narrow claims are presented herein, it should be recognized that the scope of this invention is much broader than presented by the claim. It is intended that broader claims will be submitted in an application that claims the benefit of priority from this application.

While this invention has been described with respect to at least one embodiment, the present invention can be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains and which fall within the limits of the appended claims.

1. A photovoltaic panel system comprising:
a bifacial photovoltaic panel having a front side and a back side, wherein each of the front side and the back side of the bifacial photovoltaic panel has a photovoltaic structure that generates electricity from light shining thereon;
a solar lamp positioned adjacent to the back side of the bifacial photovoltaic panel; and
a controller for activating the solar lamp during nighttime hours,
wherein the solar lamp, when activated, illuminates the back side of the bifacial photovoltaic panel to enable electricity generation from the bifacial photovoltaic panel during nighttime hours.

2. The photovoltaic panel system of claim 1 wherein the activation of the solar lamp is determined by a sensor for sensing sunlight.

3. The photovoltaic panel system of claim 1 further comprising a monofacial photovoltaic panel for powering the solar lamp.

4. The photovoltaic panel system of claim 1 wherein the activation of the solar lamp is determined by the controller responsive to a feedback signal from the monofacial photovoltaic panel.

5. The photovoltaic panel system of claim 1, wherein the solar lamp comprises a plurality of LED lights.

6. The photovoltaic panel system of claim 1, further comprising a mounting structure configured to secure the bifacial photovoltaic panel and the solar lamp in a fixed position relative to each other.

7. The photovoltaic panel system of claim 1, wherein the controller is configured to adjust the intensity of the solar lamp based on ambient light conditions.

8. The photovoltaic panel system of claim 1, wherein the controller is configured to activate the solar lamp automatically when the level of ambient light falls below a certain threshold.

9. A method of generating electricity using a photovoltaic panel system, the method comprising:
providing a bifacial photovoltaic panel having a front side and a back side, each of the front side and the back side having a photovoltaic structure that generates electricity from light shining thereon;
positioning a solar lamp adjacent to the back side of the bifacial photovoltaic panel;
generating electricity from sunlight on the front side of the bifacial photovoltaic panel during daytime hours;
activating the solar lamp during nighttime hours; and
generating electricity from the light emitted by the solar lamp and incident on the back side of the bifacial photovoltaic panel during nighttime hours.

10. The method of claim 9, further comprising adjusting an intensity of the solar lamp based on ambient light conditions.

11. The method of claim 9, further comprising securing the bifacial photovoltaic panel and the solar lamp in a fixed position relative to each other using a mounting structure.

12. The method of claim 11, wherein the mounting structure comprises anchors that secure the mounting structure to a surface.

13. The method of claim 9, wherein the solar lamp comprises a plurality of LED lights arranged in a panel configuration.

14. The method of claim 13, wherein positioning the solar lamp adjacent to the back side of the bifacial photovoltaic panel comprises attaching the panel configuration of LED lights to the back side of the bifacial photovoltaic panel using a plurality of screws.

15. A photovoltaic panel system comprising:
a bifacial photovoltaic panel having a front side and a back side, each of the front side and the back side having a photovoltaic structure that generates electricity from light shining thereon;
a light source positioned to illuminate the back side of the bifacial photovoltaic panel; and
a control unit configured to:
operate the bifacial photovoltaic panel to generate electricity from ambient light during daytime hours; and
activate the light source during nighttime hours to enable the bifacial photovoltaic panel to generate electricity from light emitted by the light source.

16. The photovoltaic panel system of claim 15, wherein the light source comprises a plurality of LED lights arranged in a panel configuration.

17. The photovoltaic panel system of claim 16, wherein the panel configuration of LED lights is attached to the back side of the bifacial photovoltaic panel using a plurality of screws.

18. The photovoltaic panel system of claim 15, further comprising a mounting structure for securing the bifacial photovoltaic panel and the solar lamp in a fixed position relative to each other.

19. The photovoltaic panel system of claim 18, wherein the mounting structure comprises anchors that secure the mounting structure to a surface.

20. The photovoltaic panel system of claim 15, wherein the control unit adjusts an intensity of the light source based on ambient light conditions, activating the light source automatically when the level of ambient light falls below a certain threshold.
